(19) United States
(12) Patent Application Publication
(10) Pub. No.: US 2021/0043433 A1
(43) Pub. Date: Feb. 11, 2021

(54) PLACING TABLE AND SUBSTRATE PROCESSING APPARATUS

(71) Applicant: Tokyo Electron Limited, Tokyo (JP)

(72) Inventors: Katsuyuki Koizumi, Kurokawa-gun (JP); Masanori Takahashi, Kurokawa-gun (JP); Shota Ezaki, Kurokawa-gun (JP)

(21) Appl. No.: 16/987,674

(22) Filed: Aug. 7, 2020

(30) Foreign Application Priority Data
Aug. 9, 2019 (JP) 2019-148133

(51) Int. Cl. H01J 37/32; F28D 7/00

(52) U.S. Cl. CPC H01J 37/32724; F28D 7/00; H01J 37/32642

(57) ABSTRACT

A placing table includes a first surface located at an outer side than a substrate; and a second surface on which the substrate is placed. A first path is formed to correspond to the first surface.

### CROSS-REFERENCE TO RELATED APPLICATION

This application claims the benefit of Japanese Patent Application No. 2019-148133 filed on Aug. 9, 2019, the entire disclosure of which is incorporated herein by reference.

### TECHNICAL FIELD

The various aspects and embodiments described herein pertain generally to a placing table and a substrate processing apparatus.

### BACKGROUND

In a substrate processing apparatus, to adjust a temperature of a substrate placed on a placing table, a coolant controlled to a preset temperature is flown into a path provided within the placing table to thereby cool the substrate (for example, Patent Document 1).

Patent Document 1: Japanese Patent Laid-open Publication No. 2006-261541

Patent Document 2: Japanese Patent Laid-open Publication No. 2011-151055

Patent Document 3: Japanese Patent No. 5,210,706

Patent Document 4: Japanese Patent No. 5,416,748

### SUMMARY

In one exemplary embodiment, a placing table includes a first surface located at an outer side than a substrate; and a second surface on which the substrate is placed. A first path is formed to correspond to the first surface.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view illustrating an example of a substrate processing apparatus according to an exemplary embodiment;

FIG. 2A and FIG. 2B are diagrams illustrating an example of a path according to the exemplary embodiment;

FIG. 3 is a diagram illustrating an example of a structure and a layout condition of the path according to the exemplary embodiment;

FIG. 4A to FIG. 4D are diagrams illustrating an example of a positional relationship between an outermost portion of a substrate and a heat source according to the exemplary embodiment; and

FIG. 5 is a diagram illustrating an example of an experimental result for a temperature of a substrate placing region depending on presence or absence of the path according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described in detail with reference to the accompanying drawings. In the various drawing, like parts will be assigned like reference numerals, and redundant description will be omitted.

[Substrate Processing Apparatus].

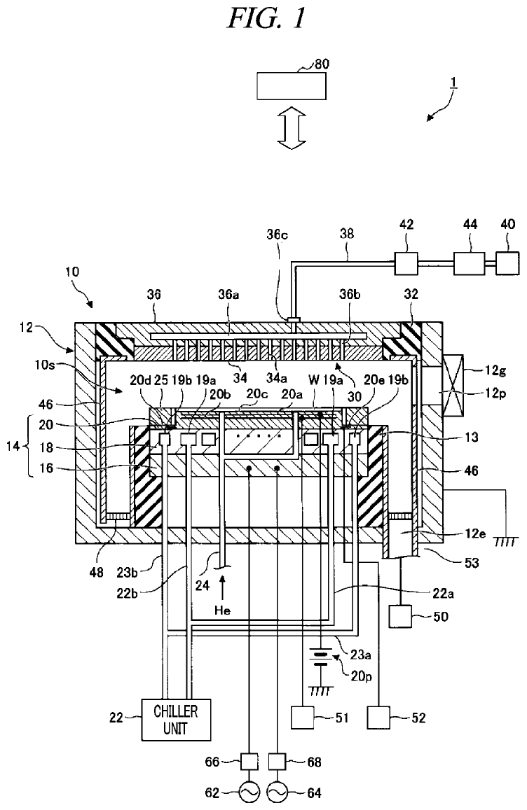

A substrate processing apparatus 1 according to an exemplary embodiment will be explained with reference to FIG. 1. FIG. 1 is a schematic cross sectional view illustrating an example of the substrate processing apparatus 1 according to the exemplary embodiment. The substrate processing apparatus 1 is equipped with a chamber 10. The chamber 10 has an internal space 10s therein. The chamber 10 includes a chamber main body 12. The chamber main body 12 has a substantially cylindrical shape. The chamber main body 12 is made of, by way of example, but not limitation, aluminum. A corrosion-resistant film is provided on an inner wall surface of the chamber main body 12. This corrosion-resistant film may be made of ceramic such as aluminum oxide or yttrium oxide.

A passage 12p is formed at a sidewall of the chamber main body 12. The substrate W is transferred between the internal space 10s and an outside of the chamber 10 through the passage 12p. The passage 12p is opened or closed by a gate valve 12g which is provided along the sidewall of the chamber main body 12.

A supporting member 13 is provided on a bottom of the chamber main body 12. The supporting member 13 is made of an insulating material. The supporting member 13 has a substantially cylindrical shape. Within the internal space 10s, the supporting member 13 extends upwards from the bottom of the chamber main body 12. The supporting member 13 has a placing table 14 at an upper portion thereof. The placing table 14 is configured to support the substrate W within the internal space 10s.

The placing table 14 has a base 18 and an electrostatic chuck 20. The placing table 14 may be further equipped with an electrode plate 16. The electrode plate 16 is made of a conductor such as, but not limited to, aluminum and has a substantially disk shape. The base 18 is provided on the electrode plate 16. The base 18 is made of a conductor such as, but not limited to, aluminum and has a substantially disk shape. The base 18 is electrically connected with the electrode plate 16.

The electrostatic chuck 20 is placed on a placing surface of the base 18, and the substrate W is placed on a placing surface of the electrostatic chuck 20. Hereinafter, the placing surface of the electrostatic chuck 20 on which the substrate W is placed will be referred to as “second surface 20c.” A main body of the electrostatic chuck 20 has a substantially disk shape and is made of a dielectric material. The electrostatic chuck 20 includes an electrode 20a embedded therein in parallel with the second surface 20c. The electrode 20a of the electrostatic chuck 20 is a film-shaped electrode. The electrode 20a of the electrostatic chuck 20 is connected to a DC power supply 20p via a switch. If a voltage from the DC power supply 20p is applied to the electrode 20a of the electrostatic chuck 20, an electrostatic attracting force is generated between the electrostatic chuck 20 and the substrate W. The substrate W is held on the electrostatic chuck 20 by this electrostatic attracting force.

The electrostatic chuck 20 has a step around the substrate, and a surface of the electrostatic chuck 20 outer than this step is used as a placing surface for an edge ring 25. With this configuration, the edge ring 25 is disposed to surround the substrate W. The edge ring 25 is configured to improve in-surface uniformity of a plasma processing upon the substrate W. The edge ring 25 may be made of, but not limited to, silicon, silicon carbide, quartz, or the like. The edge ring 25 is an example of a ring-shaped member disposed to surround the substrate and is also called a focus ring. Hereinafter, this placing surface of the electrostatic chuck 20 on which the edge ring 25 is placed will be referred to as “first surface 20d” which is located at an outer side than the substrate.

The placing table 14 according to the present exemplary embodiment includes the electrostatic chuck 20. However, the exemplary embodiment is not limited thereto. By way of example, the placing table 14 may not have the electrostatic chuck 20. In such a case, the substrate W is placed on the placing surface of the base 18, and this placing surface of the base 18 serves as the second surface 20c on which the substrate is placed. Further, the placing surface of the base 18 outer than the substrate serves as the first surface 20d located at the outer side than the substrate.

As stated above, the edge ring 25 is placed on the first surface 20d to surround the substrate W, and this first surface 20d is an outer top surface of the electrostatic chuck 20 configured to attract the edge ring 25. Further, the substrate W is placed on the second surface 20c, and this second surface 20c is an inner top surface of the electrostatic chuck 20 configured to attract the substrate W.

Below, a coolant will be described as an example of a heat exchange medium. However, the heat exchange medium is not limited thereto and may be a temperature control medium. A first path 19b configured to allow the coolant to flow therein is formed at a peripheral portion within the base 18 located under the first surface 20d. The coolant is supplied into the first path 19b via a pipeline 23a from a chiller unit 22 which is provided at an outside of the chamber 10. The coolant flows through the pipeline 23a and is supplied into the first path 19b from an inlet opening for the coolant. Then, the coolant flows to an outlet opening and is returned back into the chiller unit 22 via a pipeline 23b.

Further, a second path 19a configured to allow the coolant to flow therein is formed at a central portion within the base 18 located under the second surface 20c. The coolant is supplied into the second path 19a from the chiller unit 22 via a pipeline 22a. The coolant flows through the pipeline 22a and is supplied into the second path 19a from an inlet opening for the coolant. Then, the coolant flows to an outlet opening and is returned back into the chiller unit 22 via a pipeline 22b.

The electrostatic chuck 20 includes a first heater 20e. The first heater 20e is buried near the step of the electrostatic chuck 20 under the first surface 20d. This single first heater 20e is provided between the first surface 20d and the first path 19b. The first heater 20e is connected with a power supply 52. If a voltage from the power supply 52 is applied to the first heater 20e, the first heater 20e is heated. The first heater 20e is used to control a temperature of the edge ring 25. Further, the first heater 20e is also used to control a temperature of a local area of an outermost portion (for example, ranging from 2 mm to 3 mm from an edge of the substrate) of the substrate.

Further, the electrostatic chuck 20 is further quipped with a second heater 20b configured to control a temperature of the substrate W. The second heater 20b is buried in parallel with the electrode 20a within the electrostatic chuck 20. The second heater 20b is connected with a power supply 51. If a voltage from the power supply 51 is applied to the second heater 20b, the second heater 20b is heated. The second heater 20b is used to control the temperature of the substrate W.

In the substrate processing apparatus 1 having the above-described configuration, the temperature of the substrate W placed on the electrostatic chuck 20 is adjusted through a heat exchange between the base 18 and the coolant/heaters. Further, the first path 19b is an example of a path through which the heat exchange medium flows, corresponding to the first surface 20d. The second path 19a is an example of a path through which the heat exchange medium flows, corresponding to the second surface 20c. If the first path 19b is formed within the placing table 14, the second path 19a may be omitted.

In the present exemplary embodiment, the first path 19b and the second path 19a are connected to the chiller unit 22, which is capable of supplying the coolant into the first path 19b and the second path 19a, in parallel. However, the exemplary embodiment is not limited thereto, and the first path 19b and the second path 19a may be connected to the chiller unit 22, which is capable of supplying the coolant into the first path 19b and the second path 19a, in series. Further, two chiller units 22 may be provided and different kinds of coolants may be circulated into the first path 19b and the second path 19a, respectively, or the single chiller unit 22 may be provided and the common coolant may be supplied into the first path 19b and the second path 19a, as in the present exemplary embodiment.

The substrate processing apparatus 1 is equipped with a gas supply line 24. A heat transfer gas (e.g., a He gas) from a heat transfer gas supply mechanism is supplied into a gap between the top surface of the electrostatic chuck 20 and a rear surface of the substrate W through the gas supply line 24.

The substrate processing apparatus 1 is further equipped with an upper electrode 30. The upper electrode 30 is provided above the placing table 14. The upper electrode 30 is supported at an upper portion of the chamber main body 12 with a member 32 therebetween. The member 32 is made of a material having insulation property. The upper electrode 30 and the member 32 close a top opening of the chamber main body 12.

The upper electrode 30 may include a ceiling plate 34 and a supporting body 36. A bottom surface of the ceiling plate 34 is a surface facing the internal space 10s, and it forms and confines the internal space 10s. The ceiling plate 34 is formed of a low-resistance conductor or semiconductor having low Joule's heat. The ceiling plate 34 is provided with multiple gas discharge holes 34a which are formed through the ceiling plate 34 in a plate thickness direction.

The supporting body 36 is configured to support the ceiling plate 34 in a detachable manner. The supporting body 36 is made of a conductive material such as, but not limited to, aluminum. A gas diffusion space 36a is provided within the supporting body 36. The supporting body 36 is provided with multiple gas holes 36b which extend downwards from the gas diffusion space 36a. The multiple gas holes 36b respectively communicate with the multiple gas discharge holes 34a. Further, the supporting body 36 is provided with a gas inlet opening 36c. The gas inlet opening 36c is connected to the gas diffusion space 36a. A gas supply line 38 is connected to this gas inlet opening 36c.

A valve group 42, a flow rate controller group 44 and a gas source group 40 are connected to the gas supply line 38. The gas source group 40, the valve group 42 and the flow rate controller group 44 constitute a gas supply unit. The gas source group 40 includes a plurality of gas sources. The valve group 42 includes a plurality of opening/closing valves. The flow rate controller group 44 includes a plurality of flow rate controllers. Each of the flow rate controllers belonging to the flow rate controller group 44 may be a mass flow controller or a pressure control type flow rate controller. Each of the gas sources belonging to the gas source group 40 is connected to the gas supply line 38 via a corresponding opening/closing valve belonging to the valve group 42 and a corresponding flow rate controller belonging to the flow rate controller group 44.

In the substrate processing apparatus 1, a shield 46 is provided along the inner wall surface of the chamber main body 12 and an outer side surface of the supporting member 13 in a detachable manner. The shield 46 is configured to suppress an etching byproduct from adhering to the chamber main body 12. The shield 46 may be made of, by way of non-limiting example, an aluminum base member having a corrosion-resistant film formed on a surface thereof. The corrosion-resistant film may be formed of ceramic such as yttrium oxide.

A baffle plate 48 is provided between the supporting member 13 and the sidewall of the chamber main body 12. The baffle plate 48 may be made of, by way of example, an aluminum base member having a corrosion-resistant film (a yttrium oxide film or the like) formed on a surface thereof. The baffle plate 48 is provided with a plurality of through holes. A gas exhaust port 12e is provided at the bottom of the chamber main body 12 under the baffle plate 48. The gas exhaust port 12e is connected with a gas exhaust device 50 via a gas exhaust line 53. The gas exhaust device 50 has a pressure control valve and a vacuum pump such as a turbo molecular pump.

The substrate processing apparatus 1 is further equipped with a first high frequency power supply 62 and a second high frequency power supply 64. The first high frequency power supply 62 is configured to generate a first high frequency power. The first high frequency power has a frequency suitable for plasma formation. The frequency of the first high frequency power is in a range from, e.g., 27 MHz to 100 MHz. The first high frequency power supply 62 is connected to the base 18 via a matching device 66 and the electrode plate 16. The matching device 66 is equipped with a circuit configured to match an output impedance of the first high frequency power supply 62 and an impedance at a load side (base 18 side). Further, the first high frequency power supply 62 may be connected to the upper electrode 30 via the matching device 66. The first high frequency power supply 62 constitutes an example of a plasma generator.

The second high frequency power supply 64 is configured to generate a second high frequency power. A frequency of the second high frequency power is lower than the frequency of the first high frequency power. When the first high frequency power and the second high frequency power are used together, the second high frequency power is used as a high frequency bias power for ion attraction into the substrate W. The frequency of the second high frequency power falls within a range from, e.g., 400 kHz to 13.56 MHz. The second high frequency power supply 64 is connected to the base 18 via a matching device 68 and the electrode plate 16. The matching device 68 is equipped with a circuit configured to match an output impedance of the second high frequency power supply 64 and the impedance at the load side (base 18 side).

Here, plasma may be formed by using only the second high frequency power without using the first high frequency power, that is, by using a single high frequency power. In such a case, the frequency of the second high frequency power may be larger than 13.56 MHZ, for example, 40 MHz. The substrate processing apparatus 1 may not be equipped with the first high frequency power supply 62 and the matching device 66. The second high frequency power supply 64 constitutes an example of a plasma generator.

In the substrate processing apparatus 1, a gas is supplied from the gas supply unit into the internal space 10s to form the plasma. Further, by supplying the first high frequency power and/or the second high frequency power, a high frequency electric field is formed between the upper electrode 30 and the base 18. The generated high frequency electric field forms the plasma.

The substrate processing apparatus 1 may be further equipped with a controller 80. The controller 80 may be a computer including a processor, a storage unit such as a memory, an input device, a display device, a signal input/output interface, and so forth. The controller 80 controls the individual components of the substrate processing apparatus 1. In the controller 80, an operator may input a command or the like through the input device to manage the substrate processing apparatus 1. Further, in the controller 80, an operational status of the substrate processing apparatus 1 can be visually displayed by the display device. Furthermore, control programs and recipe data are stored in the storage unit of the controller 80. The control programs are executed by the processor of the controller 80 to allow various processings to be performed in the substrate processing apparatus 1. The processor executes the control programs and controls the individual components of the substrate processing apparatus 1 according to the recipe data.

[Path]

By flowing the coolant cooled to a preset temperature into the second path 19a provided within the base 18, the substrate W is cooled. However, it is difficult to control a temperature of a local area of an outermost portion of the substrate ranging from, for example, several millimeters from an edge of the substrate having a diameter equal to or larger than 300 mm.

As a resolution, in the placing table 14 according to the exemplary embodiment, the first path 19b is provided at an outer side than the substrate. To be specific, the first path 19b is provided at a position such as where a range of an influence of a temperature control by the coolant flown into the second path 19a is reduced, and the temperature of the outermost portion of the substrate is locally controlled. Further, in the present exemplary embodiment, a cross sectional area of the first path 19b is set to be relatively smaller than a cross sectional area of the second path 19a to increase a flow velocity. Accordingly, the temperature of the outermost portion of the substrate can be controlled more locally.

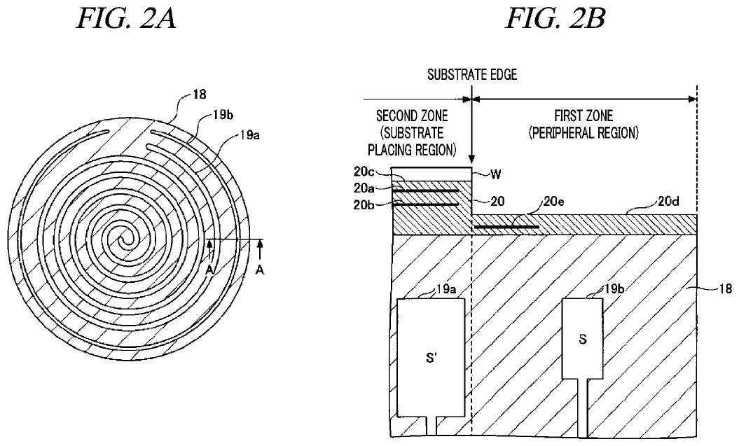

FIG. 2A and FIG. 2B are diagrams illustrating an example of the paths according to the exemplary embodiment. FIG. 2A presents a cross sectional view of the base 18. As depicted in FIG. 2A, the second path 19a is formed to have a spiral shape within the base 18. However, the shape of the second path 19a is not limited thereto, and the second path 19a may have various other shapes such as an annular shape. The first path 19b is formed to have a substantially annular shape to surround the second path 19a. However, the shape of the first path 19b is not limited thereto, and the first path 19b may be formed to have a double- or multiple-ring shape or a spiral shape, or any of various other shapes.

FIG. 2B is a cross sectional view taken along a line A-A of FIG. 2A. An outer side than the edge of the substrate W or the step of the electrostatic chuck 20 is referred to as a first zone (peripheral region), and an inner side than the edge of the substrate W or the step of the electrostatic chuck 20 is referred to as a second zone (substrate placing region). In the present exemplary embodiment, to carry out a temperature control of the outermost portion of the substrate ranging from about 2 mm to 3 mm from the edge of the substrate W, the first path 19b formed in the first zone of the base 18 is essential. The second path 19a formed in the base 18 of the second zone may be omitted.

Further, the first heater 20e configured to control the temperature of the edge ring 25 mainly disposed on the first surface 20d is provided in the first zone. In the present exemplary embodiment, the first heater 20e is provided within the electrostatic chuck 20. However, the exemplary embodiment is not limited thereto, and the first heater 20e may be provided in the base 18. The second heater 20b provided within the electrostatic chuck 20 of the first zone may be omitted.

A cross sectional area S of the first path 19b is smaller than a cross sectional area S′ of the second path 19a. Accordingly, a flow velocity of the coolant flowing in the first path 19b can be increased to be higher than a flow velocity of the coolant flowing in the second path 19a. Therefore, a heat removal effect of the first zone can be improved.

Furthermore, by using the combination of the first path 19b and the first heater 20e, the temperature control of the outermost portion of the substrate ranging from several millimeters from the edge of the substrate can be carried out with higher accuracy.

[Layout Conditions]

(Condition 1)

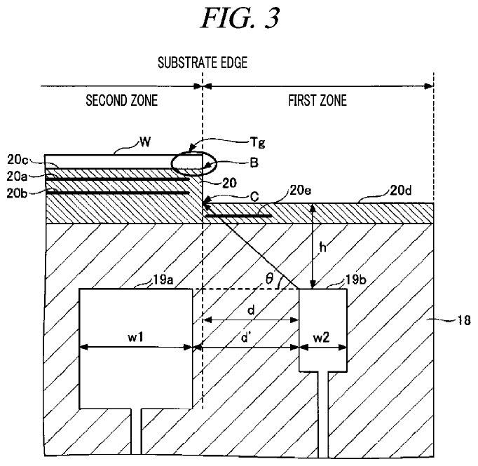

The first path 19b is used to control the temperature of the edge ring 25 placed on the first surface 20d. Further, the first path 19b is also used to control the temperature of the outermost portion of the substrate. A layout condition for the first path 19b will be explained with reference to FIG. 3. FIG. 3 is a diagram illustrating an example of a structure of the first path 19b and the second path 19a and a layout condition therefor according to the exemplary embodiment. When a vertical distance from the first surface 20d to the first path 19b is defined as h and a horizontal distance from a boundary between the first surface 20d and the second surface 20c to the first path 19b is defined as d, the first path 19b is provided in a region where a condition 1 of d>h is satisfied. The condition 1 may be substituted by tan⁻¹(h/d)≤45°.

In the present exemplary embodiment, a temperature control of a temperate control target area Tg of the outermost portion of the substrate shown in FIG. 3 is performed. The temperature control target area Tg is an area ranging 2 mm to 5 mm from an end portion of the second surface 20c which is the top surface of the electrostatic chuck 20. For structural reasons, a reaction product generated in a substrate processing may easily adhere to an angled portion formed by the end portion of the second surface 20c and the boundary between the first surface 20d and the second surface 20c, and this angled portion may be easily heated by heat inputted from plasma. For these reasons, it is important to control the temperature of the temperature control target area Tg. Further, by improving temperature controllability of the outermost region of the substrate, a yield can be improved and productivity can be increased. From the above-stated reasons, in the present exemplary embodiment, the first path 19b of the first zone is formed to satisfy the aforementioned condition 1 and the following conditions, and the temperature of the temperature control target area Tg is controlled by using this first path 19b.

Moreover, though the top surface (the first surface 20d and the second surface 20c) of the placing table 14 has the step in the present exemplary embodiment, no step may be provided. If the top surface of the placing table 14 does not have the step, a position C is overlapped with a position B. Further, heat from the first path 19b is transferred to the position B via the position C.

Thus, whether the top surface of the placing table 14 has the step or does not have the step, a local temperature control of the temperature control target area Tg is enabled by controlling a temperature of the position C which is the shortest distance through which the heat from the first path 19b moves.

(Condition 2)

Further, when the second path 19a formed within the base 18 of the second zone has a width w1 in a horizontal direction and the first path 19b formed within the base 18 of the first zone has a width w2 in the horizontal direction, it is desirable that w1 is larger than w2 (w1>w2). In case that a flow rate of the coolant flowing in the first path 19b and the second path 19a is constant and a length of the first path 19b in a height direction is equal to or less than a length of the second path 19a in the height direction, a flow velocity of the coolant increases with a decrease of the width of the first path 19b. As a result, the flow velocity of the coolant flowing through the first path 19b can be increased higher than the flow velocity of the coolant flowing through the second path 19a. Accordingly, heat removal control of the first zone can be improved, and the temperature control of the outermost portion of the substrate can be carried out with higher accuracy.

(Condition 3)

Furthermore, when a horizontal distance from the first path 19b to the second path 19a is defined as d′, it is desirable that d′ is larger than d (d′>d). With this configuration, the heat removal control of the first zone can be improved, so that the temperature controllability of the outermost portion of the substrate can be further ameliorated.

(Condition 4)

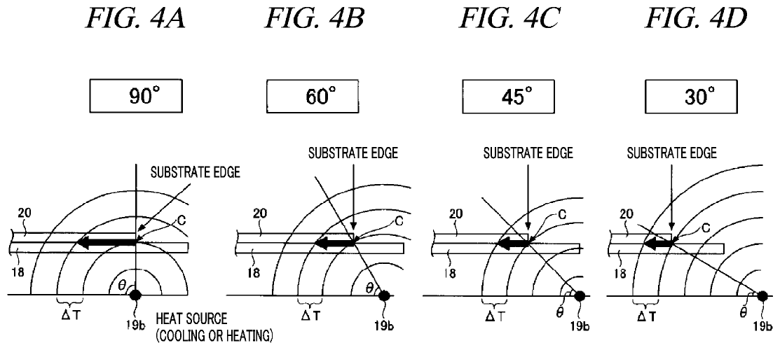

In addition, a condition for an angle θ when the first path 19b is set as a heat source will be explained with reference to FIG. 4A to FIG. 4D. FIG. 4A to FIG. 4D are diagrams illustrating an example of a positional relationship between the heat source and the outermost portion of the substrate near the edge of the substrate according to the exemplary embodiment. Though the following description will be provided for the example where the first path 19b is set as the heat source, the heat source is not limited thereto, and it can be the first heater 20e provided in the first zone. Further, in FIG. 4A to FIG. 4D, the first path 19b serving as the heat source is marked by a dot for the convenience of explanation.

The angle θ is an angle formed by an extension line of a top surface of the first path 19b and a line connecting the position C and an inner end (which is closer to the temperature control target area Tg) of the top surface of the first path 19b, as shown in FIG. 3. When the angle θ is 90° as shown in FIG. 4A, a value of ΔT, that is, a temperature influence range in the placing table 14 indicted by an arrow ‘←’ is largest among those shown in FIG. 4A to FIG. 4D. As illustrated in FIG. 4B to FIG. 4D, as the angle θ decreases to 60°, 45° and 30°, the value of ΔT, that is, the length of the arrow ‘←’ is shortened, which implies that the temperature influence range in the placing table 14 is reduced.

That is, since the temperature influence range in the placing table 14 gets smaller with the decrease of the angle θ, a local control of the temperature is enabled, which is desirable. If the angle θ is equal to or smaller than 60°, the relative effect of the temperature influence range upon the angle θ is reduced. By way of example, if the angle θ is equal to or smaller than 60°, it is deemed that the temperature control target area Tg can be locally controlled.

[Experiments]

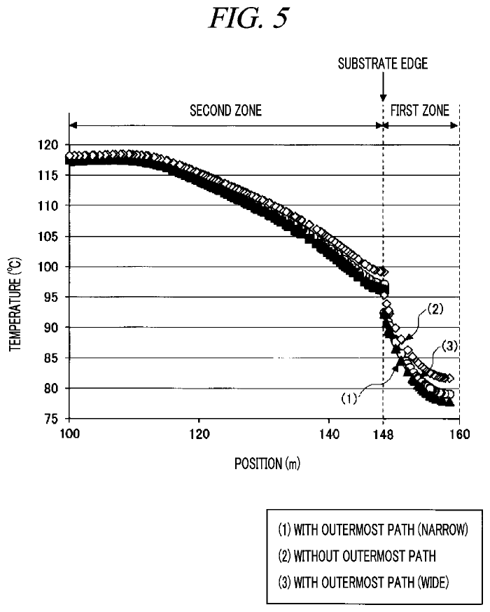

Now, measurement results of a temperature of the substrate placing region in two cases where the first path 19b is provided and the first path 19b is not provided will be described with reference to FIG. 5. FIG. 5 is a diagram illustrating an example of an experiment result for the temperature of the substrate placing region depending on presence or absence of the first path 19b according to the exemplary embodiment. Here, the temperature of the substrate placing region refers to a temperature of a rear surface of the substrate when the substrate is placed on the second surface 20c, or a temperature of the second surface 20c on which the substrate is placed.

(1) of FIG. 5 indicates a case where the first path 19b is provided but it is narrow. The case where the first path 19b is narrow is a case where the relationship between the width w1 of the second path 19a in the horizontal direction and the width w2 of the first path 19b in the horizontal direction satisfies a condition of w1>w2, as shown in FIG. 3.

(2) of FIG. 5 indicates a case where the first path 19b is not provided. (3) of FIG. 5 indicates a case where the first path 19b for the control of the outermost portion of the substrate is provided. In this case, the first path 19b is wider than that in the case of (1) of FIG. 5. The case where the first path 19b is wide is a case where the relationship between the width w1 of the second path 19a in the horizontal direction and the width w2 of the first path 19b in the horizontal direction satisfies a condition of w1=w2 or w1<w2.

In all of these cases (1) to (3), the second path 19a and the second heater 20b are provided in the second zone.

A horizontal axis of FIG. 5 indicates a position on the substrate in a diametrical direction thereof, and a vertical axis represents the temperature of the substrate placing region. In a graph of FIG. 5, 100 mm from a center of the substrate having a diameter of 300 mm is set as the left end of the graph, and FIG. 5 show a temperature of the second zone ranging up to 148 mm of the edge of the substrate and a temperature of the first zone ranging from 148 mm of the edge of the substrate to 160 mm of an outer side of the substrate.

As can be seen from the result of FIG. 5, as compared to the case (2) where the first path 19b is not provided and the case (3) where the first path 19b is wide, a cooling effect by the coolant is increased in the case (1) where the first path 19b is narrow in the first zone, so that the temperature of the outermost portion of the substrate is reduced. That is, in the case (1) where the first path 19b is narrow, temperature controllability of the outermost portion of the substrate can be improved, as compared to the cases (2) and (3).

As a result, in the cases (1) and (3) where the first path 19b is provided, the temperature difference ΔT of the substrate placing region is increased, as compared to the case (2) where the first path 19b is not provided. Thus, the temperature of the outermost portion (ranging from 2 mm to 3 mm from the edge of the substrate) of the substrate can be locally reduced. Furthermore, in the case (1) where the first path 19b is narrow, the temperature of the outermost portion of the substrate can be further reduced as compared to the case (3) where the first path 19b is wider than that in the case (1).

As stated above, according to the placing table 14 and the substrate processing apparatus 1 of the present exemplary embodiment, it is possible to control the temperature of the outermost portion of the substrate.

Further, though the present exemplary embodiment has been described for the case where the first path 19b is mainly used as the heat source as a means to control the temperature of the outermost portion of the substrate, the exemplary embodiment is not limited thereto. By way of example, the first heater 20e may be used as the means to control the temperature of the outermost portion of the substrate, or a combination of the first path 19b and the first heater 20e may be used. Further, besides the first path 19b and/or the first heater 20e, a heating element or a piezo element may be used as the heat source.

In addition, though the single first heater 20e is provided between the first surface 20d and the first path 19b in the above-described exemplary embodiment, the number of the first heater 20e is not limited thereto, and multiple first heaters 20e may be provided. In case that the multiple first heaters 20e are provided, it is desirable that at least one of the multiple heaters 20e is provided between the first surface 20d and the first path 19b.

It should be noted that the placing table and the substrate processing apparatus according to the exemplary embodiments of the present disclosure are illustrative in all aspects and are not limiting. Various change and modifications may be made within the scope of the present disclosure. Unless contradictory, the disclosures in the various exemplary embodiments can be combined appropriately.

The substrate processing apparatus of the present disclosure may be applicable to any of various types of apparatuses such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus and a helicon wave plasma (HWP) apparatus.

Further, though the above exemplary embodiments have been described for the case where the plasma processing apparatus is used as an example of the substrate processing apparatus 1, the substrate processing apparatus is not limited to the plasma processing apparatus. By way of example, the substrate processing apparatus 1 may be a heat treatment apparatus configured to heat-treat the substrate W by a heating mechanism such as a heater without forming plasma, for example, a thermal ALD apparatus, a thermal CVD (Chemical Vapor Deposition) apparatus, or the like. Further, the substrate processing apparatus 1 may be an etching apparatus or a film forming apparatus.

According to the exemplary embodiment, it is possible to control the temperature of the outermost portion of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A placing table comprising a first surface located at an outer side than a substrate; and a second surface on which the substrate is placed,
wherein a first path is formed to correspond to the first surface.

2. The placing table of claim 1,
wherein when a vertical distance between the first surface and the first path is h and a horizontal distance from a boundary between the first surface and the second surface to the first path is d, d is larger than h (d>h).

3. The placing table of claim 1,
wherein a second path is formed to correspond to the second surface, and
when a width of the second path in a horizontal direction is w1 and a width of the first path in the horizontal direction is w2, w1 is larger than w2 (w1>w2).

4. The placing table of claim 3,
wherein when a horizontal distance from the first path to the second path is d′, d′ is larger than d (d′>d).

5. The placing table of claim 3,
wherein the first path and the second path are connected to a chiller unit, which is allowed to supply a heat exchange medium into the first path and the second path, in parallel.

6. The placing table of claim 3,
wherein the first path and the second path are connected to a chiller unit, which is allowed to supply a heat exchange medium into the first path and the second path, in series.

7. The placing table of claim 1,
wherein a ring member is placed on the first surface to surround the substrate.

8. The placing table of claim 7,
wherein the first surface is an outer top surface of an electrostatic chuck, configured to attract the ring member.

9. The placing table of claim 8,
wherein the second surface is an inner top surface of the electrostatic chuck, configured to attract the substrate.

10. The placing table of claim 8,
wherein the electrostatic chuck comprises a first heater which is disposed between the first surface and the first path and configured to control a temperature of the ring member.

11. The placing table of claim 8,
wherein the electrostatic chuck comprises a second heater which is disposed in parallel with the second surface and configured to control a temperature of the substrate.

12. The placing table of claim 1,
wherein the first path is formed at an outer side than an edge of the substrate.

13. A substrate processing apparatus comprising a chamber configured to perform a plasma processing or a heat treatment therein; and a placing table configured to place a substrate on an electrostatic chuck within the chamber,
wherein the placing table comprises:
a first surface located at an outer side than the substrate; and
a second surface on which the substrate is placed,
wherein a first path is formed to correspond to the first surface.

14. The substrate processing apparatus of claim 13,
wherein when a vertical distance between the first surface and the first path is h and a horizontal distance from a boundary between the first surface and the second surface to the first path is d, d is larger than h (d>h).

15. The substrate processing apparatus of claim 13, further comprising:
a chiller unit,
wherein a second path is formed to correspond to the second surface, and
the chiller unit is configured to supply a heat exchange medium into the first path and the second path.
